(19) United States
(12) Patent Application Publication
(10) Pub. No.: US 2025/0142948 A1
(43) Pub. Date: May 1, 2025

(54) INTEGRATED CIRCUIT DEVICES WITH SELF-ALIGNED VIA-TO-JUMPER CONNECTIONS

(71) Applicant: Intel Corporation, Santa Clara, CA (US)

(72) Inventors: Robin Chao, Portland, OR (US); Chiao-Ti Huang, Portland, OR (US); Guowei Xu, Portland, OR (US); Yang Zhang, Rio Rancho, NM (US); Ting-Hsiang Hung, Beaverton, OR (US); Tao Chu, Portland, OR (US); Feng Zhang, Hillsboro, OR (US); Chia-Ching Lin, Portland, OR (US); Anand S. Murthy, Portland, OR (US); Conor P. Puls, Portland, OR (US); Kan Zhang, Hillsboro, OR (US)

(73) Assignee: Intel Corporation, Santa Clara, CA (US)

(21) Appl. No.: 18/498,318

(22) Filed: Oct. 31, 2023

(51) Int. Cl. H01L 27/088; H01L 23/498; H01L 29/08; H01L 29/66; H01L 29/78

(52) U.S. Cl. CPC H10D 84/834; H01L 23/49816; H01L 23/49822; H01L 23/49838; H10D 30/024; H10D 30/6211; H10D 62/154; H10D 62/158

(57) ABSTRACT

An IC device with one or more transistors may also include one or more vias and jumpers for delivering power to the transistors. For instance, a via may be coupled to a power plane. A jumper may be connected to the via and an electrode of a transistor. With the via and jumper, an electrical connection is built between the power plane and the electrode. The via may be self-aligned. The IC device may include a dielectric structure at a first side of the via. A portion of the jumper may be at a second side of the via. The second side opposes the first side. The dielectric structure and the portion of the jumper may be over another dielectric structure that has a different dielectric material from the dielectric structure. The via may be insulated from another electrode of the transistor, which may be coupled to a ground plane.

### BACKGROUND

Integrated circuit (IC) fabrication usually includes two stages. The first stage is referred to as the front end of line (FEOL). The second stage is referred to as the back end of line (BEOL). In the FEOL, individual semiconductor devices components (e.g., transistor, capacitors, resistors, etc.) can be patterned on a wafer. In the BEOL, metal layers, vias, and insulating layers can be formed to get the individual components interconnected. The BEOL usually starts with forming the first metal layer on the wafer. The first metal layer is often called M0. More metal layers can be formed on top of M0, and these metal layers are often called M1, M2, and so on. Metal layers can be arranged at both the frontside and the backside of the semiconductor devices. One or more metal layers may be used for delivering power to the semiconductor devices.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an IC device with backside power delivery, according to some embodiments of the disclosure.

FIG. 2 illustrates an IC device with a self-aligned via and a jumper for power delivery, according to some embodiments of the disclosure.

FIGS. 3A-3D illustrate a process of forming an IC device with a self-aligned via, according to some embodiments of the disclosure.

FIGS. 4A-4G illustrate a process of forming a hybrid dielectric layer, according to some embodiments of the disclosure.

FIGS. 5A-5F illustrate a process of forming a self-aligned via and a jumper based on a hybrid dielectric layer, according to some embodiments of the disclosure.

FIGS. 6A and 6B are top views of a wafer and dies that may include one or more IC devices with self-aligned via-to-jumper connection, according to some embodiments of the disclosure.

FIG. 7 is a side, cross-sectional view of an example IC package that may include one or more IC devices with self-aligned via-to-jumper connection, according to some embodiments of the disclosure.

FIG. 8 is a cross-sectional side view of an IC device assembly that may include components having one or more IC devices with self-aligned via-to-jumper connection, according to some embodiments of the disclosure.

FIG. 9 is a block diagram of an example computing device that may include one or more components including one or more IC devices with self-aligned via-to-jumper connection, according to some embodiments of the disclosure.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

Currently available technologies enable scaling below 5 nanometers (or even below 3 nanometers) by delivering power on the backside of a die or wafer. Backside power delivery can eliminate the need to share interconnect resources between signal and power lines on the frontside. Instead, power delivery network is moved to the backside while signals can be carried by frontside interconnects. Backside power delivery can also enable cost savings as it can remove the need for a power delivery interconnect from lower metal layers at the frontside. It can also facilitate optimal fabrication of different metal layers. For instance, wider metal lines can be used for VDD and VSS, while thinner metal lines can be used for signal delivery.

One of the approaches for backside power delivery is to have a via and a jumper transfer power from the backside power delivery network to electrodes of transistors. This approach can improve power efficiency and increase area scaling. A good power delivery network can deliver constant and stable supply voltage to active circuits on the IC. It can be critical to have good contact between the via and jumper to form a good power delivery network. However, currently available technologies for forming vias and jumpers suffer from the drawback of having defects (e.g., voids) in the area where the via is connected to the jumper. Such defects can increase resistance in the power delivery network and reduce the power efficiency and performance of IC devices.

Embodiments of the present disclosure may improve on at least some of the challenges and issues described above by providing IC devices with self-aligned via-to-jumper connections for power or signal delivery. In various embodiments of the present disclosure, an IC device may include one or more transistors, one or more vias, and one or more jumpers. The vias and jumpers may be used for delivering power or signal to the transistors. For instance, a via may be coupled to a power plane. A jumper may be connected to the via and an electrode (e.g., a source electrode, a drain electrode, or a gate electrode) of a transistor. With the via and jumper, an electrical connection is built between the power plane and the electrode. The connection between the via and the jumper may be self-aligned. The self-aligned connection may be achieved by using dielectric structures having different materials. For instance, the IC device may include a dielectric structure at a side of the via. A portion of the jumper may be at the opposite side of the via. The dielectric structure and the portion of the jumper may be over a dielectric liner that has a different dielectric material from the dielectric structure.

In some embodiments, to achieve the self-aligned connection between the via and the jumper, a hybrid dielectric layer may be formed. The hybrid dielectric layer includes the dielectric liner and an additional dielectric liner over the dielectric liner. The two dielectric liners have different dielectric materials. For example, the dielectric liner may have an oxide, while the additional dielectric liner may have a nitride. The dielectric constants of the two dielectric liners may be different. The via may be formed in an opening defined by the hybrid dielectric layer so that the two dielectric liners wrap around the via. After the via is formed, a portion of the additional dielectric layer may be removed to form an opening. The rest of the additional dielectric layer may be the dielectric structure described above. A portion of the jumper may be formed in the opening, which ensures that the portion of the jumper has a good connection with the via. The connection is self-aligned and formed by using the hybrid dielectric layer. That way, a good contact of the via to the jumper can be achieved without any major change to the process of forming the via and jumper. Compared with currently available technologies, the present disclosure provides an efficient approach to increase the contact area between via and jumper and to remove sources of defects.

It should be noted that, in some settings, the term “nanoribbon” has been used to describe an elongated semiconductor structure that has a substantially rectangular transverse cross-section (e.g., a cross-section in a plane perpendicular to the longitudinal axis of the structure), while the term “nanowire” has been used to describe a similar structure but with a substantially circular or square transverse cross-sections. In the following, a single term “nanoribbon” is used to describe an elongated semiconductor structure independent of the shape of the transverse cross-section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections. A longitudinal axis of a structure refers to a line (e.g., an imaginary line) that runs down the center of the structure in a direction perpendicular to a transverse cross-section of the structure.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the term “or” refers to an inclusive “or” and not to an exclusive “or.” The phrase “A and/or B” or the phase “A or B” means (A), (B), or (A and B). For the purposes of the present disclosure, the phrase “A, B, and/or C” or the phase “A, B, or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

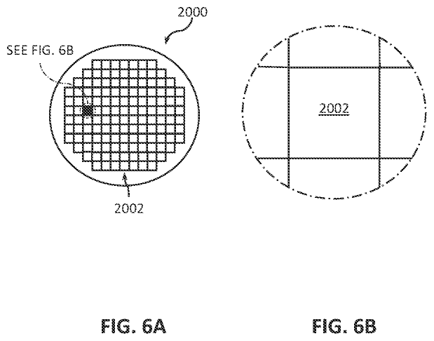

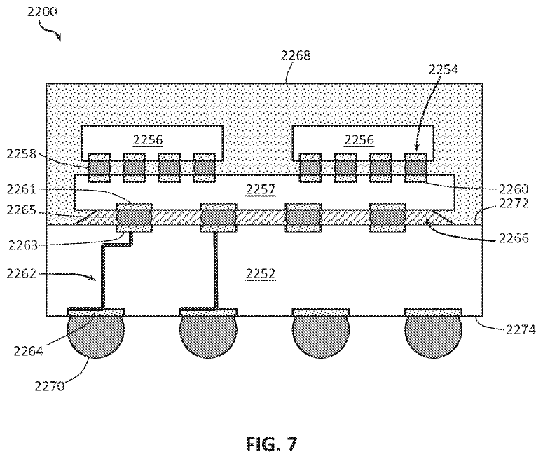

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 6A and 6B, such a collection may be referred to herein without the letters, e.g., as “FIG. 6.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using e.g., Physical Failure Analysis (PFA) would allow determination of presence of vias having self-aligned connections to jumpers as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various vias having self-aligned connections to jumpers as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

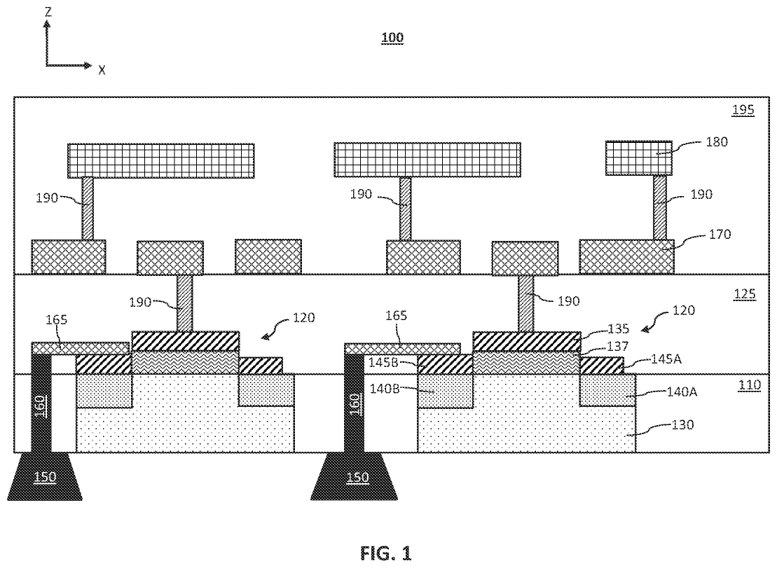

FIG. 1 illustrates an IC device 100 with backside power delivery, according to some embodiments of the disclosure. The IC device 100 includes a support structure 110, transistors 120 (individually referred to as “transistor 120”), an electrical insulator 125, backside metal lines 150 (individually referred to as “backside metal line 150”), deep vias 160 (individually referred to as “deep via 160”), jumpers 165 (individually referred to as “jumper 165”), frontside metal lines 170 (individually referred to as “frontside metal line 170”), and frontside metal lines 180 (individually referred to as “frontside metal line 180”), vias 190A-190C, and another electrical insulator 195. In other embodiments, the IC device 100 may include fewer, more, or different components. For example, the IC device 100 may include more transistors or other semiconductor devices not shown in FIG. 1. As another example, the IC device 100 may include a different number of deep vias, jumpers, or metal lines.

The support structure 110 may be any suitable structure, such as a substrate, a die, a wafer, or a chip, based on which the transistor 120 can be built. The support structure 110 may, e.g., be the wafer 2000 of FIG. 6A, discussed below, and may be, or be included in, a die, e.g., the singulated die 2002 of FIG. 6B, discussed below. In some embodiments, the support structure 110 may be a semiconductor substrate composed of semiconductor material systems including, for example, N-type or P-type materials systems, and, in some embodiments, the channel region 130, described herein, may be a part of the support structure 110. In some embodiments, the semiconductor substrate may be a crystalline substrate formed using a bulk silicon or a silicon-on-insulator substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of Group III-V, Group II-VI, or Group IV materials. In some embodiments, the substrate may be non-crystalline. In some embodiments, the support structure may be a printed circuit board (PCB) substrate. One or more transistors, such as the transistor 120 may be built on the support structure 110.

Although a few examples of materials from which the support structure 110 may be formed are described here, any material that may serve as a foundation upon which an IC may be built falls within the spirit and scope of the present disclosure. In various embodiments, the support structure 110 may include any such substrate, possibly with some layers and/or devices already formed thereon, not specifically shown in the present figures. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure 110 may provide material “support” in that, e.g., the IC devices/structures described herein are build based on the semiconductor materials of the support structure 110. However, in some embodiments, the support structure 110 may provide mechanical support.

Each transistor 120 may be a field-effect transistor (FET), such as metal-oxide-semiconductor FET (MOSFET), tunnel FET (TFET), fin-based transistor (e.g., FinFET), nanoribbon-based transistor, nanowire-based transistor, gate-all-around (GAA) transistor, other types of FET, or a combination of both. A transistor 120 includes a semiconductor structure that includes a channel region 130, a source region 140A, and a drain region 140B. The semiconductor structure of the transistor 120 may be at least partially in the support structure 110. The support structure 110 may include a semiconductor material, from which at least a portion of the semiconductor structure is formed. The semiconductor structure of the transistor 120 (or a portion of the semiconductor structure, e.g., the channel region 130) may be a planar structure or a non-planar structure. A non-planar structure is a three-dimensional structure, such as fin, nanowire, or nanoribbon. A non-planar structure may have a longitudinal axis and a transvers cross-section perpendicular to the longitudinal axis. In some embodiments, a dimension of the non-planar structure along the longitudinal axis may be greater than dimensions along other directions, e.g., directions along axes perpendicular to the longitudinal axis.

The channel region 130 includes a channel material. The channel material may be composed of semiconductor material systems including, for example, N-type or P-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group III of the periodic table (e.g., Al, Ga, In), and a second sub-lattice of at least one element of group V of the periodic table (e.g., P, As, Sb). In some embodiments, the channel material may include a compound semiconductor with a first sub-lattice of at least one element from Group II of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nanometers and 100 nanometers, including all values and ranges therein.

For some example N-type transistor embodiments (i.e., for the embodiments where the transistor 120 is an NMOS (N-type metal-oxide-semiconductor) transistor or an N-type TFET), the channel material may advantageously include a III-V material having a high electron mobility, such as, but not limited to InGaAs, InP, InSb, and InAs. For some such embodiments, the channel material may be a ternary III-V alloy, such as InGaAs, GaAsSb, InAsP, or InPSb. For some InxGa1-xAs fin embodiments, In content (x) may be between 0.6 and 0.9, and may advantageously be at least 0.7 (e.g., In0.7Ga0.3As). In some embodiments with highest mobility, the channel material may be an intrinsic III-V material, i.e., a III-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material 304 may be relatively low, for example below 1015 dopant atoms per cubic centimeter (cm-3), and advantageously below 10¹³ cm⁻³. These materials may be amorphous or polycrystalline, e.g., having a crystal grain size between 0.5 nanometers and 100 nanometers.

For some example P-type transistor embodiments (i.e., for the embodiments where the transistor 120 is a PMOS (P-type metal-oxide-semiconductor) transistor or a P-type TFET), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic III-V (or IV for P-type devices) material and not intentionally doped with any electrically active impurity. In alternate embodiments, one or more a nominal impurity dopant level may be present within the channel material, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³. These materials may be amorphous or polycrystalline, e.g., having a crystal grain size between 0.5 nanometers and 100 nanometers.

In some embodiments, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, aluminum zinc oxide, or tungsten oxide. In general, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front end components such as logic devices.

As noted above, the channel material may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

The source region 140A and the drain region 140B are connected to the channel region 130. The source region 140A and the drain region 140B each include a semiconductor material with dopants. In some embodiments, the source region 140A and the drain region 140B have the same semiconductor material, which may be the same as the channel material of the channel region 130. A semiconductor material of the source region 140A or the drain region 140B may be a Group IV material, a compound of Group IV materials, a Group III/V material, a compound of Group III/V materials, a Group II/VI material, a compound of Group II/VI materials, or other semiconductor materials. Example Group II materials include zinc (Zn), cadmium (Cd), and so on. Example Group III materials include aluminum (Al), boron (B), indium (In), gallium (Ga), and so on. Example Group IV materials include silicon (Si), germanium (Ge), carbon (C), etc. Example Group V materials include nitrogen (N), phosphorus (P), arsenic (As), antimony (Sb), and so on. Example Group VI materials include sulfur(S), selenium (Se), tellurium (Te), oxygen (O), and so on. A compound of Group IV materials can be a binary compound, such as SiC, SiGe, and so on. A compound of Group III/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the source region 140A and the drain region 140B are the same type. In other embodiments, the dopants of the source region 140A and the drain region 140B may be different (e.g., opposite) types. In an example, the source region 140A has N-type dopants and the drain region 140B has P-type dopants. In another example, the source region 140A has P-type dopants and the drain region 140B has N-type dopants. Example N-type dopants include Te, S, As, tin (Sn), Si, Ga, Se, S, In, Al, Cd, chlorine (Cl), iodine (I), fluorine (F), and so on. Example P-type dopants include beryllium (Be), Zn, magnesium (Mg), Sn, P, Te, lithium (Li), sodium (Na), Ga, Cd, and so on.

In some embodiments, the source region 140A and the drain region 140B may be highly doped, e.g., with dopant concentrations of about 1·10²¹ cm⁻³, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the source region 140A and the drain region 140B may be the regions having dopant concentration higher than in other regions, e.g., higher than a dopant concentration in the channel region 130, and, therefore, may be referred to as “highly doped” (HD) regions.

The channel region 130 may include one or more semiconductor materials with doping concentrations significantly smaller than those of the source region 140A and the drain region 140B. For example, in some embodiments, the channel material of the channel region 130 may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material is still significantly lower than the dopant level in the source region 140A and the drain region 140B, for example below 10¹⁵ cm⁻³ or below 10¹³ cm⁻³. Depending on the context, the term “S/D terminal” may refer to a S/D region or a S/D contact or electrode of a transistor.

The transistor 120 also includes an electrode 145A over the source region 140A and an electrode 145B over the drain region 140B. The electrode 145A may be referred to as a source electrode or source contact. The electrode 145B may be referred to as a drain electrode or drain contact. The electrode 145A and the electrode 145B are electrically conductive and may be coupled to source and drain terminals, respectively, for receiving power. The electrode 145A or the electrode 145B includes one or more electrically conductive materials, such as metals. Examples of metals in the electrode 145A and the electrode 145B may include, but are not limited to, ruthenium (Ru), copper (Cu), cobalt (Co), palladium (Pd), platinum (Pt), nickel (Ni), and so on.

The transistor 120 also includes a gate that is over or wraps around at least a portion of the channel region 130. The gate includes a gate electrode 135 and a gate insulator 137. The gate electrode 135 can be coupled to a gate terminal that controls gate voltages applied on the transistor 120. The gate electrode 135 may include one or more gate electrode materials, where the choice of the gate electrode materials may depend on whether the transistor 120 is a P-type transistor or an N-type transistor. For a P-type transistor, gate electrode materials that may be used in different portions of the gate electrode may include, but are not limited to, Ru, Pd, Pt, Co, Ni, and conductive metal oxides (e.g., ruthenium oxide). For an N-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 135 may include a stack of a plurality of gate electrode materials, where zero or more materials of the stack are workfunction (WF) materials and at least one material of the stack is a fill metal layer. Further materials/layers may be included next to the gate electrode for other purposes, such as to act as a diffusion barrier layer or/and an adhesion layer.

The gate insulator 137 separates at least a portion of the channel region 130 from the gate electrode 135 so that the channel region 130 is insulated from the gate electrode 135. In some embodiments, the gate insulator 137 may wrap around at least a portion of the channel region 130. The gate insulator 137 may also wrap around at least a portion of the source region 140A or the drain region 140B. At least a portion of the gate insulator 137 may be wrapped around by the gate electrode. The gate insulator 137 includes an electrical insulator, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc.

In the embodiments of FIG. 1, the transistors 120 may receive power from a backside power delivery network that includes the backside metal lines 150. The backside metal lines 150 may also be referred to as backside interconnects or power interconnects. In some embodiments, the backside metal lines 150 may be in the same backside metal layer. In other embodiments, the backside metal lines 150 may be in different backside metal layers. In some embodiments, each backside metal line 150 may be a power plane of the IC device 100. In some embodiments, a backside metal line 150 may be, or may be coupled to, a VDD terminal. In some embodiments, the backside metal line 150 may facilitate delivery of a positive supply voltage to the electrode 145B, versus the electrode 145A may receive a negative supply voltage or may be coupled to a ground plane. The transistor 120 may be an N-type transistor, e.g., a NMOS. In other embodiments, the backside metal line 150 may facilitate delivery of a negative supply voltage to the electrode 145B or couple the electrode 145B to ground. The transistor may be a P-type transistor, e.g., a PMOS transistor.

Power may be delivered from the backside metal line 150 to the corresponding transistor 120 through the corresponding deep via 160 and jumper 165. The deep vias 160 and jumpers 165 are conductive and include one or more conductive materials, such as metals, including the metals described above. The deep via 160 may be referred to as a power via. The jumper 165 may be referred to as a power jumper. As shown in FIG. 1, each deep via 160 is connected to a backside metal line 150 and to a jumper 165. Each jumper 165 is connected to the electrode 145B. Thus, the backside metal line 150, the deep via 160, and the jumper 165 constitute a conductive path to the electrode 145B. The jumper 165 provides an electrical connection between the deep via 160 and the electrode 145B. The jumper 165 may be, or may include, a conductive wire or other types of conductive structures. Even though the jumper 165 is connected to the electrode 145B in FIG. 1, the jumper 165, or an additional jumper in the IC device 100, may be connected to the electrode 145A so that power can be delivered to the electrode 145A in other embodiments.

As shown in FIG. 1, the deep via 160 extends from the backside of the support structure 110 towards the frontside of the support structure 110. In some embodiments, the deep via 160 has a longitudinal axis along the Z axis. The widths of various portions of the deep via 160 along the X axis may be the same or substantially similar. In some embodiments, a width of the deep via 160 along the X axis is in a range from approximately 10 nanometers to approximately 20 nanometers. The deep via 160 may penetrate at least part of the support structure 110. In some embodiments, the deep via 160 may penetrate the whole support structure 110 along the Z axis. The deep via 160 may be a through-silicon-via.

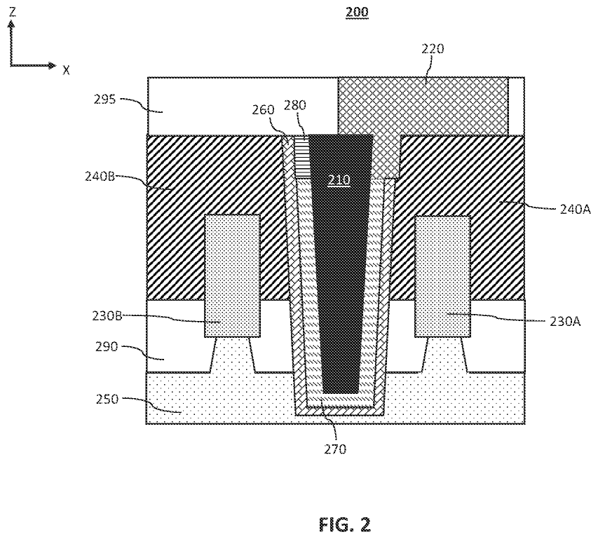

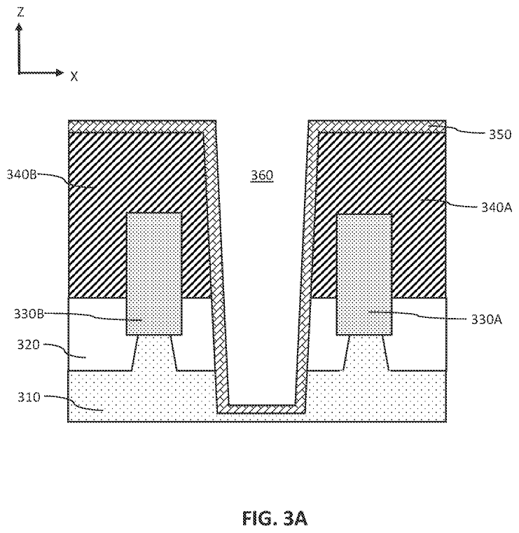

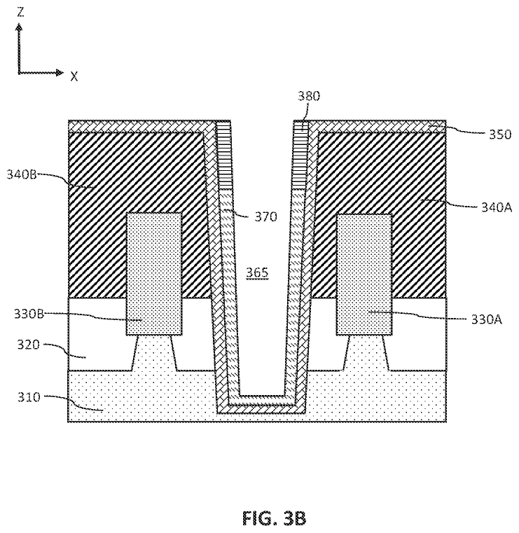

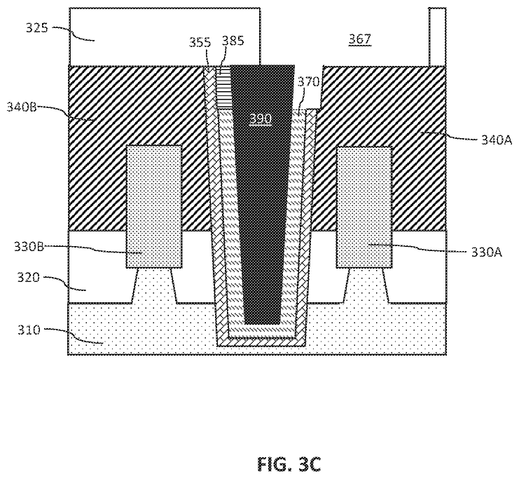

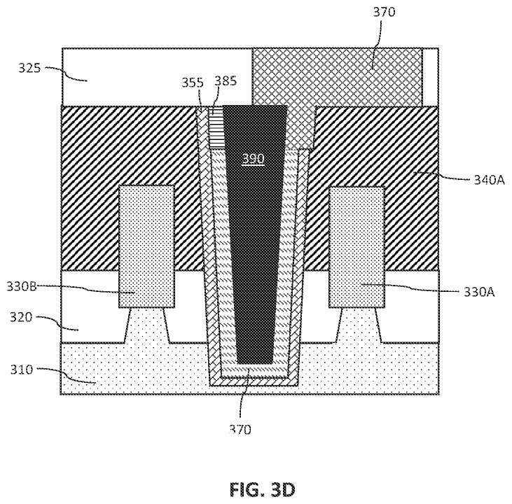

In some embodiments, the deep vias 160 may be self-aligned, e.g., for achieving good contact with the jumper 165s. More details regarding self-aligned vias are described below in conjunction with FIG. 2. In some embodiments, the jumpers 165 may be formed after the deep via 160s is formed. More details regarding forming the deep vias 160 and the jumpers 165 are described below in conjunction with FIGS. 3A-3D, 4A-4F, and 5A-5F.

Each of the electrodes 145A and 145B, gate electrode 135, jumper 165, and deep via 160 may be at least partially surrounded by the electrical insulator to avoid undesirable electrical connection or coupling. The electrical insulator 195 may include an electrical insulator, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc.

The frontside metal lines 170 and 180 are stacked over the support structure 110, the transistor 120, and the electrical insulator 125 along the Z axis. A frontside metal line 170 is coupled to the gate electrode 135 of the transistor 120 through the via 190A. In some embodiments, the frontside metal line 170 may be used to deliver signal (e.g., control signals) to the gate electrode 135. The other frontside metal lines 170 are coupled to the frontside metal lines 180 through the vias 190B and 190C, respectively. In other embodiments, the electrical connections of the frontside metal lines 170 and 180 may be different. Even though not shown in FIG. 1, the frontside metal line 170 or 180 may be coupled with other devices than the transistor 120, such as diodes, power sources, resistors, capacitors, inductors, sensors, transceivers, receivers, antennas.

In some embodiments, the frontside metal lines 170 may constitute the metal layer that is arranged closest to the transistors 120 and may be the first BEOL layer at the frontside of the support structure 110. In some embodiments, the metal layer may be referred to as M0. The frontside metal lines 180 may constitute the second metal layer at the frontside, which may be referred to as M1. There may be one or more metal layers that are arranged on top of the frontside metal lines 170, which may be referred to as M3, M4, and so on. The frontside metal lines 170 are coupled to the frontside metal lines 180 through the vias 190B and 190C. The frontside metal lines 170 and 180 are at least partially surrounded by the electrical insulator 195. The electrical insulator 125 or 195 may include one or more electrically insulating materials, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc.

FIG. 2 illustrates an IC device 200 with a self-aligned via 210 and a jumper 220 for power delivery, according to some embodiments of the disclosure. The IC device 200 also includes two semiconductor structures 230A and 230B (collectively referred to as “semiconductor structures 230” and “semiconductor structure 230”), two conductive structures 240A and 240B (collectively referred to as “conductive structures 240” and “conductive structure 240”), semiconductor substrate 250, three dielectric structures 260, 270, and 280, and electrical insulators 290 and 295. In other embodiments, the IC device 200 may include fewer, more, or different components. The IC device 200 may be an example of a portion of the IC device 100 in FIG. 1.

The self-aligned via 210 is a via that extends along the Z axis. The self-aligned via 210 may be an example of the deep via 160 in FIG. 1. In some embodiments, the self-aligned via 210 may be a through-silicon via. The self-aligned via 210 is connected to the jumper 220. The self-aligned via 210 may be coupled to a power plane (not shown in FIG. 2). The self-aligned via 210 and the jumper 220 are conductive structures that may be used for delivering power to the semiconductor structure 230A. As shown in FIG. 2, the jumper 220 is also connected to the conductive structure 240A so that the self-aligned via 210 is coupled to the conductive structure 240A through the jumper 220. The conductive structure 240A is over the semiconductor structure 230A.

The semiconductor structures 230 may each be a source region, channel region, or drain region of a transistor, e.g., the transistor 120 in FIG. 1. The conductive structures 240 may each constitute a source electrode, gate electrode, or drain electrode of a transistor. In an example, the semiconductor structure 230A may be a source region of a transistor, and the semiconductor structure 230B may be a drain region of the same transistor. In another example, the semiconductor structure 230A may be a drain region of a transistor, and the semiconductor structure 230B may be a source region of the same transistor. In yet another example, the semiconductor structure 230A may be a source or drain region of a transistor, while the semiconductor structure 230B may be a source or drain region of another transistor. In yet another example, the semiconductor structure 230A or 230B may be a channel region of a transistor.

The semiconductor structures 230 are over the semiconductor substrate 250 along the Z axis. The semiconductor substrate 250 may be an example of the support structure 110 in FIG. 1. The semiconductor substrate 250 may facilitate formation of the semiconductor structures 230. In some embodiments, the semiconductor structures 230 may be formed using an epitaxial process. The semiconductor substrate 250 is separated from the conductive structures 240 by the electrical insulator 290. The electrical insulator 290 may include one or more electrically insulating materials, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc.

The dielectric structure 260 may be a liner that wraps around the self-aligned via 210. In some embodiments, the dielectric structure 260 may include a nitride (e.g., silicon nitride, titanium nitride, etc.), carbide (e.g., silicon carbide, etc.), or other dielectric materials. The dielectric structure 260 may abut the conductive structures 240. For instance, the dielectric structure 260 touches the conductive structures 240. The dielectric structure 270 is wrapped around by the dielectric structure 260. As shown in FIG. 2, a length of the dielectric structure 270 along the Z axis is smaller than a length of the dielectric structure 260 along the Z axis.

The dielectric structure 270 is between the dielectric structure 260 and the self-aligned via 210. The dielectric structure 270 may have a different dielectric material from the dielectric structure 260. In some embodiments, the dielectric structure 270 has a low-k dielectric material, such as dielectric materials having relatively low dielectric constant (e.g., dielectric constant lower than 4.2 or lower than 3.9). The dielectric material in the dielectric structure 270 may be an oxide, such as fluorine doped silicon dioxide, carbon-doped oxide, porous silicon dioxide, and so on. The self-aligned via 210 may be formed after the dielectric structures 260 and 270 are formed. For instance, the self-aligned via 210 may be formed by providing one or more conductive materials into an opening region defined by the dielectric structures 260 and 270. The dimensions and location of the self-aligned via 210 may be controlled by controlling the dimensions and locations of the dielectric structures 260 and 270.

The dielectric structure 280 is over a portion of the dielectric structure 270 along the Z axis. The dielectric structure 280 may have a different dielectric material from the dielectric structure 270. For instance, the dielectric structure 280 may include a nitride, while the dielectric structure 270 may include an oxide. The dielectric structure 280 is at one side of the self-aligned via 210, i.e., the left side in FIG. 2. A portion of the jumper 220 is at an opposite side (i.e., the right side) of the self-aligned via 210 form the dielectric structure 280. In other embodiments, the dielectric structure 280 may be at the right side of the self-aligned via 210 and a portion of the jumper 220 may be at the left side of the self-aligned via 210. In some embodiments, the bottom surface of the dielectric structure 280 is aligned with the bottom surface of the jumper 220. The bottom surface of the dielectric structure 280 may touch a portion of the top surface of the dielectric structure 270, and the bottom surface of the jumper 220 may touch another portion of the top surface of the dielectric structure 270.

The dielectric structure 280 and a portion of the dielectric structure 260 may facilitate insulation between the self-aligned via 210 and the conductive structure 240B. In some embodiments, the conductive structure 240B may be at a different electrical potential from the self-aligned via 210 during the operation of the IC device 200. For instance, the self-aligned via 210 may be coupled to a power plane, while the conductive structure 240B may be coupled to a ground plane.

Another portion of the jumper 220 is over part of the self-aligned via 210 and part of the conductive structure 240A along the Z axis. This portion of the jumper 220 is surrounded by the electrical insulator 295. The electrical insulator 295 is over the self-aligned via 210, conductive structures 240, and the dielectric structures 260 and 280. The electrical insulator 295 may include one or more electrically insulating materials, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc.

FIGS. 3A-3D illustrate a process of forming an IC device with a self-aligned via, according to some embodiments of the disclosure. The process may be used to form at least part of the IC device 100 or 200. In FIG. 3A, a support structure 310, an insulator layer 320, two semiconductor structures 330A and 330B (collectively referred to as “semiconductor structures 330” and “semiconductor structure 330”), two conductive structures 340A and 340B (collectively referred to as “conductive structures 340” and “conductive structure 340”), and a dielectric layer 350 have been formed. The support structure 310 may be an example of the support structure 110 in FIG. 1 or the semiconductor substrate 250 in FIG. 2. The insulator layer 320 is over the support structure 310 along the Z axis. The semiconductor structures 330 each extend along the Z axis and each have a portion surrounded by the insulator layer 320. The insulator layer 320 may be an example of the electrical insulator 290 in FIG. 2. The conductive structure 340A wraps around a portion of the semiconductor structure 330A, and the conductive structure 340B wraps around a portion of the semiconductor structure 330B. The conductive structures 340 may be examples of the conductive structures 240 in FIG. 2. The dielectric layer 350 may be formed by depositing a dielectric material (e.g., a nitride) over the conductive structures 340 and over an opening region between the conductive structures 340. The dielectric layer 350 defines a new opening region 360 between the conductive structures 340. The opening region 360 is also between the semiconductor structures 330.

In FIG. 3B, new dielectric layers 370 and 380 are formed in the opening region 360. The dielectric layer 380 is above the dielectric layer 370. The dielectric layer 370 is over a portion of the dielectric layer 350, and the dielectric layer 380 is over another portion of the dielectric layer 350. In some embodiments, the dielectric layer 370 is formed with a first dielectric material. The dielectric layer 380 is formed with a second dielectric material. The two dielectric materials may be different. For instance, the two dielectric materials may have different dielectric constants. In an example, the dielectric constant of the first dielectric material may be lower than the dielectric constant of the second dielectric material. The dielectric layers 370 and 380 define a new opening region 365.

In FIG. 3C, a conductive structure 390 is formed in the opening region 365. For instance, the opening region 365 is filled with one or more conductive materials, e.g., metals. A metal may be deposited into the opening region 365 to form the conductive structure 390. The conductive structure 390 may be an example of the deep vias 160 in FIG. 1 or an example of the self-aligned via 210 in FIG. 2. Also, a portion of the dielectric layer 355 is removed to form a new dielectric layer 355 that wraps around the conductive structure 390. The conductive structure 390 is partially wrapped around by the dielectric layer 370, which is between the conductive structure 390 and the dielectric layer 355. A portion of the dielectric layer 380 is removed to form a new dielectric layer 385.

The dielectric layer 385 is at the right side of the conductive structure 390. The left side of the conductive structure 390 abuts a new opening region 367. A portion of the opening region 367 is formed due to the removal of the portion of the dielectric layer 380. Another portion of the opening region 367 is formed in an insulator layer 325 that is over the conductive structures 340.

In FIG. 3D, a conductive structure 395 is formed in the opening region 367. The opening region 367 may be filled with one or more conductive materials, e.g., metals. A metal may be deposited into the opening region 367 to form the conductive structure 395. The conductive structure 395 may be an example of the jumpers 165 in FIG. 1 or an example of the jumper 220 in FIG. 2.

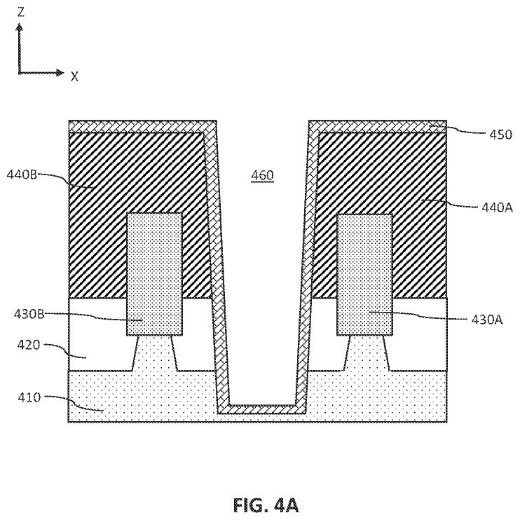

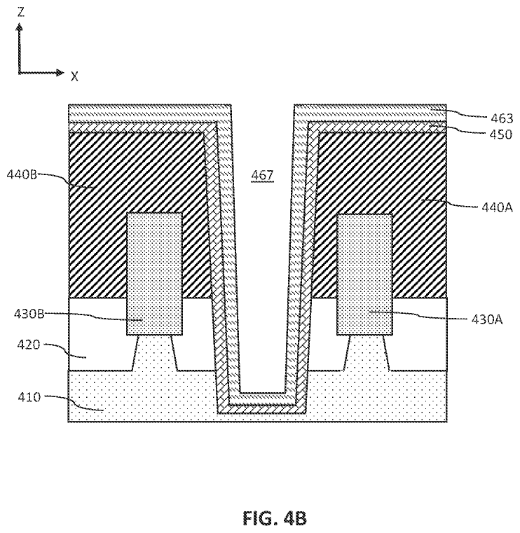

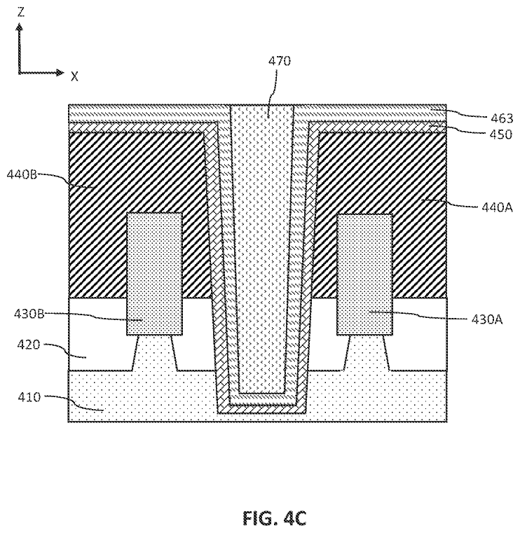

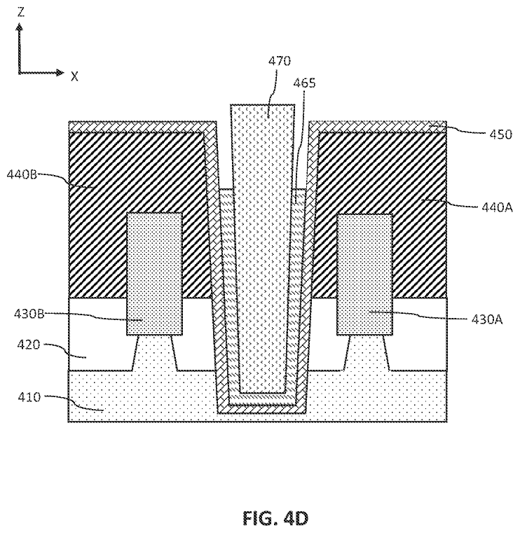

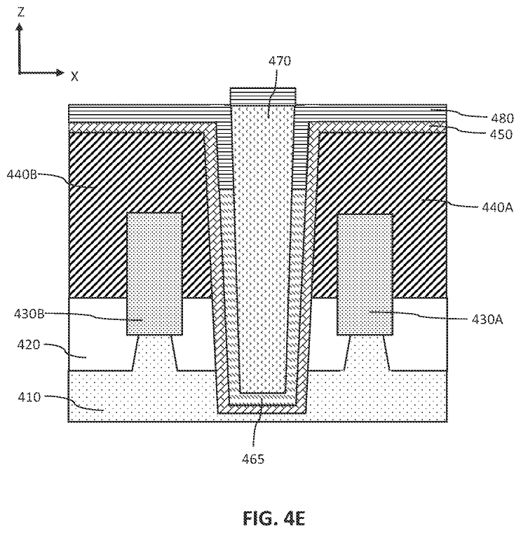

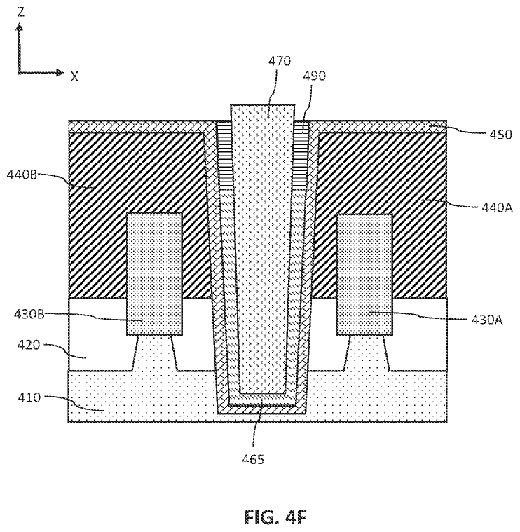

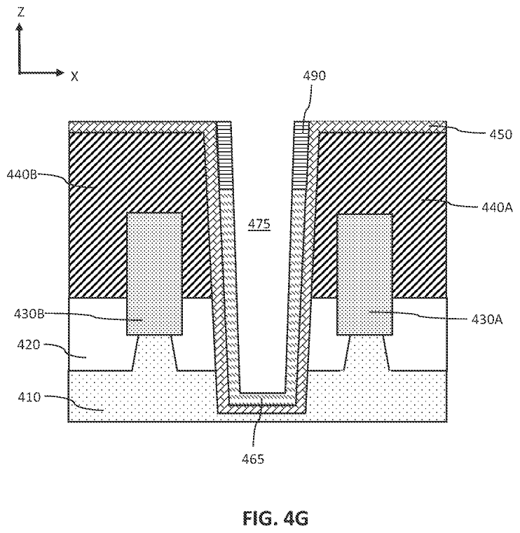

FIGS. 4A-4G illustrate a process of forming a hybrid dielectric layer, according to some embodiments of the disclosure. In FIG. 4A, a support structure 410, an insulator layer 420, two semiconductor structures 430A and 430B (collectively referred to as “semiconductor structures 430” and “semiconductor structure 430”), two conductive structures 440A and 440B (collectively referred to as “conductive structures 440” and “conductive structure 440”), and a dielectric layer 450 have been formed. The support structure 410 may be an example of the support structure 110 in FIG. 1 or the semiconductor substrate 250 in FIG. 2. The insulator layer 420 is over the support structure 410 along the Z axis. The semiconductor structures 430 each extend along the Z axis and each have a portion surrounded by the insulator layer 420. The insulator layer 420 may be an example of the electrical insulator 290 in FIG. 2. The conductive structure 440A wraps around a portion of the semiconductor structure 430A, and the conductive structure 440B wraps around a portion of the semiconductor structure 430B. The conductive structures 440 may be examples of the conductive structures 240 in FIG. 2. The dielectric layer 450 may be formed by depositing a dielectric material (e.g., a nitride) over the conductive structures 440 and over an opening region between the conductive structures 440. The dielectric layer 450 defines a new opening region 460 between the conductive structures 440. The opening region 460 is also between the semiconductor structures 430.

In FIG. 4B, a new dielectric layer 463 is formed in the opening region 460. The dielectric layer 463 is wrapped around by the dielectric layer 450. As shown in FIG. 4B, various portions of the dielectric layer 450 are between various portions of the dielectric layer 463 and the conductive structures 440. In some embodiments, the dielectric layer 450 is formed with a first dielectric material. The dielectric layer 463 is formed with a second dielectric material. The two dielectric materials may be different. For instance, the first dielectric material may be a nitride, and the second dielectric material may be an oxide. In some embodiments, the first dielectric material has a higher dielectric constant than the second dielectric material. The dielectric layer 463 defines a new opening region 467.

In FIG. 4C, the opening region 467 is filled with a polymer material and forms a polymer structure 470. The polymer structure 470 is at least partially surrounded by the dielectric layer 463. The polymer structure 470 may be formed by depositing the polymer material into the opening region 467. In some embodiments, excessive polymer material may be deposited onto the top surface of the dielectric layer 463. Such excessive polymer material may be removed after the deposition, e.g., through a polish process, to form the polymer structure 470 and to reveal the top surface of the dielectric layer 463.

In FIG. 4D, the dielectric layer 463 is recessed and a portion of the dielectric layer 463 is removed, e.g., using isotropic etch. A new dielectric layer 465 is formed. Also, openings between the dielectric layer 450 and the polymer structure 470 are formed.

In FIG. 4E, a dielectric material 480 is deposited into the openings between the dielectric layer 450 and the polymer structure 470. The dielectric material 480 is also deposited onto the top surface of the dielectric layer 450 and the top surface of the polymer structure 470. The dielectric material 480 may be a nitride or an oxide. In some embodiments, the dielectric material 480 may have a dielectric constant that is higher than the dielectric constant of the dielectric layer 465.

In FIG. 4F, some of the dielectric material 480 is removed to form a dielectric layer 490. The dielectric layer 490 is surrounded by the dielectric layer 450. Also, the dielectric layer 490 wraps around a portion of the polymer structure 470. The top surface of the dielectric layer 490 may be aligned with the top surface of the dielectric layer 450 in a direction along the Z axis. The dielectric layer 465 and the dielectric layer 490 constitute the hybrid dielectric layer, i.e., a layer with at least two different dielectric materials. The hybrid dielectric layer is wrapped around by the dielectric layer 450.

In FIG. 4G, the polymer structure 470 is removed, e.g., through an etch or polish process. An opening region 475 is formed, and the opening region 475 is surrounded by the hybrid dielectric layer. The hybrid dielectric layer is between the opening region 475 and part of the dielectric layer 450. The hybrid dielectric layer may be used to form a self-aligned deep via and a jumper.

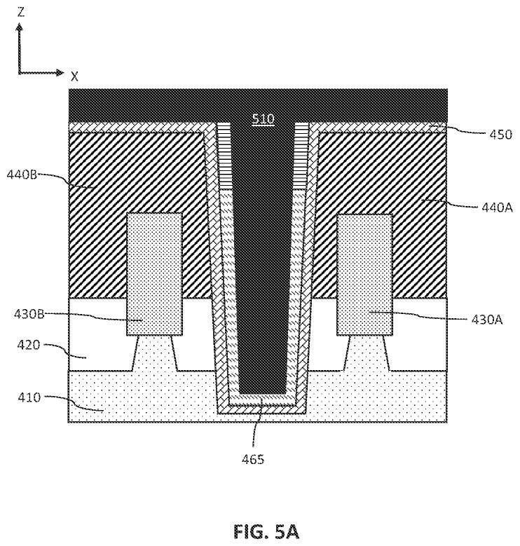

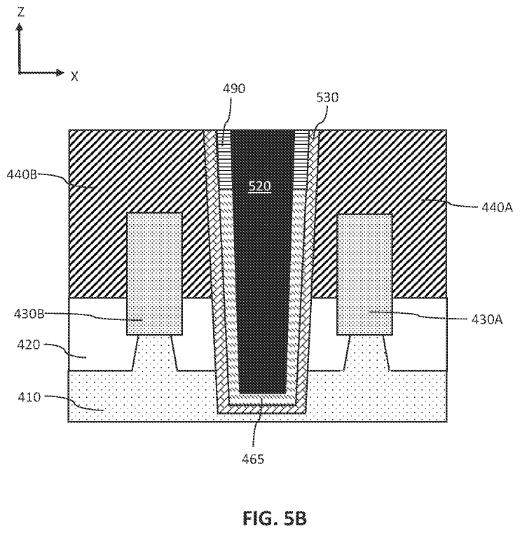

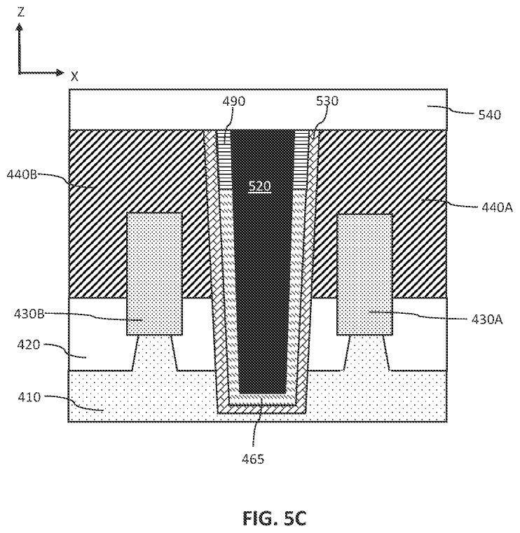

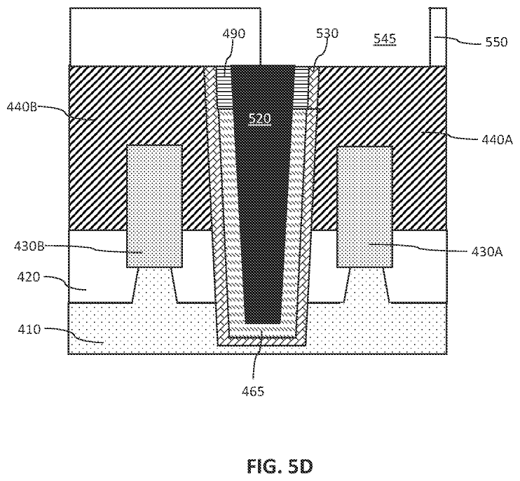

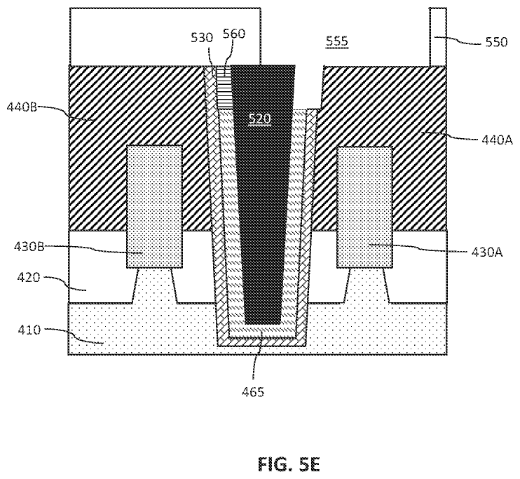

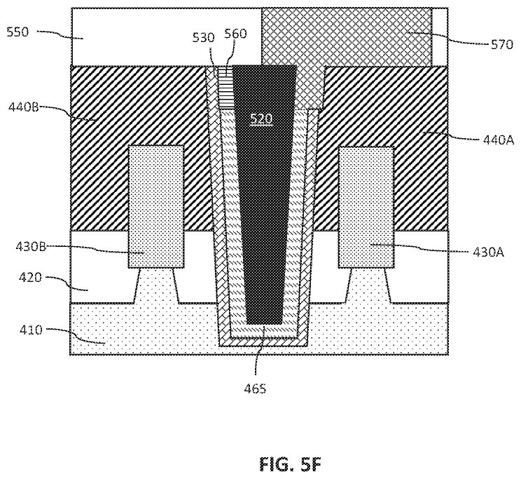

FIGS. 5A-5F illustrate a process of forming a self-aligned via and a jumper based on a hybrid dielectric layer, according to some embodiments of the disclosure. An example of the hybrid dielectric layer may be the hybrid dielectric layer formed in FIG. 4F. The step in FIG. 5A may be performed after the step illustrated in FIG. 4G. In FIG. 5A, a conductive structure 510 is formed in the opening region 475 and over the top surface of the dielectric layer 450 and the top surface of the dielectric layer 490. In some embodiments, the conductive structure 510 may be formed by depositing a metal into the opening region 475 and towards the top surface of the dielectric layer 450 and the top surface of the dielectric layer 490.

In FIG. 5B, a removal process is performed to remove part of the conductive structure 510 and part of the dielectric layer 450. A conductive structure 520 and a dielectric layer 530 are formed. The conductive structure 520 is a portion of the conductive structure 510, i.e., the portion that is not removed. Similarly, the dielectric layer 530 is a portion of the dielectric layer 450, i.e., the portion that is not removed. The top surface of the conductive structure 520 may be aligned with the top surface of the dielectric layer 530 in a direction along the Z axis. Also, the top surface of the conductive structure 520 may be aligned with the top surface of the dielectric layer 490 in a direction along the Z axis. The conductive structure 520 can be self-aligned given the presence of the hybrid dielectric layer that includes the dielectric layer 490 and the dielectric layer 530. The conductive structure 520 may be a self-aligned deep via, such as the deep vias 160 in FIG. 1 or the self-aligned via 210 in FIG. 2.

In FIG. 5C, an insulator layer 540 is formed over the conductive structure 440, the dielectric layer 490, the dielectric layer 530, and the conductive structure 520. The insulator layer 540 may include one or more electrical insulators, such as the ones described above.

In FIG. 5D, an opening region 545 is formed in the insulator layer 540. The insulator layer is changed to a new insulator layer 550 that surrounds the opening region 545. The opening region 545 may be formed through an etch or polish process.

In FIG. 5E, the opening region 545 is expanded and a new opening region 555 is formed by removing a portion of the dielectric layer 490, e.g., the portion that abuts or is closer to the conductive structure 440A. The portion of the dielectric layer 490 may be removed through an etch process. In embodiments where the dielectric layer 490 is formed with a nitride, the etch process may be a nitride etch process. The rest of the dielectric layer 490 becomes a dielectric layer 560. The dielectric layer 560 is closer to the conductive structure 440B than to the conductive structure 440A.

In FIG. 5F, the opening region 555 is filled with a conductive material, and a conductive structure 570 is formed. The conductive structure 570 may be a jumper, such as one of the jumpers 165 in FIG. 1 or the jumper 220 in FIG. 2. The conductive structure 570 touches the conductive structure 520 and the conductive structure 440A to build an electrical connection between the conductive structure 520 and the conductive structure 440A.

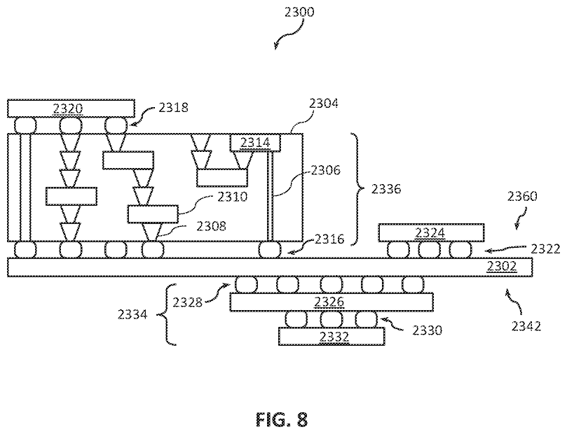

FIGS. 6A and 6B are top views of a wafer 2000 and dies 2002 that may include one or more IC devices with self-aligned via-to-jumper connection, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 7. The wafer 2000 may be composed of semiconductor material and may include one or more dies 2002 having IC devices formed on a surface of the wafer 2000. An IC device may include one or more vias having self-aligned connections to jumpers. Examples of the IC device may include the IC device 100 in FIG. 1. Each of the dies 2002 may be a repeating unit of a semiconductor product that includes any suitable IC (e.g., ICs with vias having self-aligned connections to jumpers as described herein). After the fabrication of the semiconductor product is complete (e.g., after manufacture of metal lines as described herein), the wafer 2000 may undergo a singulation process in which each of the dies 2002 is separated from one another to provide discrete “chips” of the semiconductor product. In particular, devices that include vias having self-aligned connections to jumpers as disclosed herein may take or include components that take the form of the wafer 2000 (e.g., not singulated) or the form of the die 2002 (e.g., singulated). The die 2002 may include one or more diodes, one or more transistors (e.g., one or more III-N transistors as described herein) as well as, optionally, supporting circuitry to route electrical signals to the III-N diodes with n-doped wells and capping layers and III-N transistors, as well as any other IC components. In some embodiments, the wafer 2000 or the die 2002 may implement an electrostatic discharge (ESD) protection device, a radio frequency front-end device, a memory device (e.g., a static random-access memory (SRAM) device), a logic device (e.g., an AND, OR, NAND, or NOR gate), or any other suitable circuit element. Multiple ones of these devices may be combined on a single die 2002.

FIG. 7 is a side, cross-sectional view of an example IC package 2200 that may include one or more IC devices with self-aligned via-to-jumper connection, according to some embodiments of the disclosure. In some embodiments, the IC package 2200 may be a system-in-package (SiP).

As shown in FIG. 7, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 7 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 7 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 7 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 8.

The dies 2256 may take the form of any of the embodiments of the die 2002 discussed herein and may include any of the embodiments of an IC device with vias having self-aligned connections to jumpers. In embodiments in which the IC package 2200 includes multiple dies 2256, the IC package 2200 may be referred to as a multi-chip package. Importantly, even in such embodiments of an MCP implementation of the IC package 2200, one or more IC devices with self-aligned via-to-jumper connection may be provided in a single chip, in accordance with any of the embodiments described herein. The dies 2256 may include circuitry to perform any desired functionality. For example, one or more of the dies 2256 may be ESD protection dies, one or more of the dies 2256 may be logic dies (e.g., silicon-based dies), one or more of the dies 2256 may be memory dies (e.g., high bandwidth memory), etc. In some embodiments, any of the dies 2256 may include one or more backside metal layers, e.g., vias having self-aligned connections to jumpers as discussed above; in some embodiments, at least some of the dies 2256 may not include any III-N diodes with n-doped wells and capping layers.

The IC package 2200 illustrated in FIG. 7 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 7, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 8 is a cross-sectional side view of an IC device assembly 2300 that may include components having one or more IC devices with self-aligned via-to-jumper connection, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices with self-aligned via-to-jumper connection in accordance with any of the embodiments disclosed herein; e.g., any of the IC packages discussed below with reference to the IC device assembly 2300 may take the form of any of the embodiments of the IC package 2200 discussed above with reference to FIG. 7 (e.g., may include vias having self-aligned connections to jumpers in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 8 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 7), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 6B), an IC device (e.g., the IC device 100 of FIG. 1), or any other suitable component. In particular, the IC package 2320 may include one or more IC devices with self-aligned via-to-jumper connection as described herein. Although a single IC package 2320 is shown in FIG. 8, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a loose pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 8, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other Group III-V and Group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF devices, power amplifiers, power management devices, antennas, arrays, sensors, and microelectromechanical systems (MEMS) devices may also be formed on the interposer 2304. In some embodiments, the IC devices with self-aligned via-to-jumper connection as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 8 includes a package-on-package structure 2334 coupled to the second face 2342 of the circuit board 2302 by coupling components 2328. The package-on-package structure 2334 may include an IC package 2326 and an IC package 2332 coupled together by coupling components such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

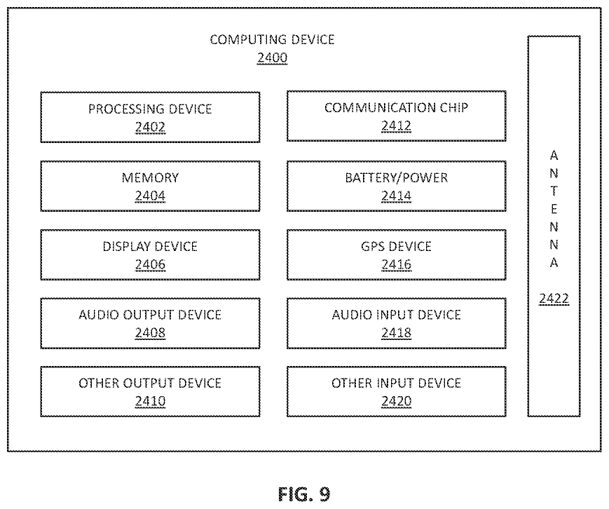

FIG. 9 is a block diagram of an example computing device 2400 that may include one or more components including one or more IC devices with self-aligned via-to-jumper connection, according to some embodiments of the disclosure. For example, any suitable ones of the components of the computing device 2400 may include a die (e.g., the die 2002 of FIG. 6B) including vias having self-aligned connections to jumpers, according to some embodiments of the disclosure. Any of the components of the computing device 2400 may include an IC device (e.g., the IC devices in FIGS. 1A and 1B) and/or an IC package (e.g., the IC package 2200 of FIG. 7). Any of the components of the computing device 2400 may include an IC device assembly (e.g., the IC device assembly 2300 of FIG. 8).

A number of components are illustrated in FIG. 9 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC (system-on-chip) die.

Additionally, in various embodiments, the computing device 2400 may not include one or more of the components illustrated in FIG. 9, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices as described herein may be particularly advantageous for use as part of ESD circuits protecting power amplifiers, low-noise amplifiers, filters (including arrays of filters and filter banks), switches, or other active components. In some embodiments, IC devices as described herein may be used in PMICs, e.g., as a rectifying diode for large currents. In some embodiments, IC devices as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or

corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.

Example 1 provides an integrated circuit (IC) device, including a transistor including a source region, a drain region, and an electrode over the source region or the drain region; a first conductive structure at least partially over the source region or the drain region in a first direction; a second conductive structure connected to the first conductive structure and the electrode, the second conductive structure including a first portion and a second portion; and a dielectric structure at a first side of the first conductive structure, in which: the first portion of the second conductive structure is over the electrode in a second direction that is perpendicular to the first direction, the second portion of the second conductive structure is at a second side of the first conductive structure, and the second side opposes the first side in the first direction.

Example 2 provides the IC device according to example 1, in which: the dielectric structure abuts a first portion of the first conductive structure, a second portion of the first conductive structure is wrapped around by an additional dielectric structure, and the second portion of the first conductive structure is over the first portion of the first conductive structure in the second direction

Example 3 provides the IC device according to example 2, in which the dielectric structure has a different dielectric material from the additional dielectric structure.

Example 4 provides the IC device according to any one of examples 1-3, in which the electrode is over the source region, the transistor further includes an additional electrode over the drain region, and the dielectric structure is between the first conductive structure and the additional electrode.

Example 5 provides the IC device according to any one of examples 1-4, in which the first conductive structure is coupled to a power plane.

Example 6 provides the IC device according to example 5, further including a support structure including a semiconductor material, the support structure having a first surface and a second surface opposing the first surface in the second direction, in which the second conductive structure is closer to the first surface of the support structure than to the second surface of the support structure.

Example 7 provides the IC device according to example 6, in which the power plane is closer to the second surface of the support structure than to the first surface of the support structure.

Example 8 provides an integrated circuit (IC) device, including a power plane; a via coupled to the power plane, the via having a first surface and a second surface opposing the first surface; an electrode over a semiconductor region of a transistor; a conductive structure connected to the via and to the electrode; and a dielectric structure, in which the dielectric structure abuts the first surface of the via, and a portion of the conductive structure abuts the second surface of the via.

Example 9 provides the IC device according to example 8, further including an additional electrode over an additional semiconductor region of the transistor, in which the additional electrode is coupled to a ground plane.

Example 10 provides the IC device according to example 8 or 9, further includes an additional dielectric structure over the dielectric structure and the portion of the conductive structure, in which the additional dielectric structure abuts the first surface and the second surface of the via.

Example 11 provides the IC device according to example 10, in which the additional dielectric structure has a different dielectric material from the dielectric structure.

Example 12 provides the IC device according to any one of examples 8-11, further including a layer including an electrical insulator; and a support structure over the layer, the support structure including a semiconductor material, in which the layer is between the electrode and the support structure.

Example 13 provides the IC device according to example 12, in which the via extends from a first surface of the layer to a second surface of the layer.

Example 14 provides a method of forming an integrated circuit (IC) device, the method including forming a first opening region between semiconductor structures, at least part of the opening region surrounded by a conductive structure; forming a dielectric layer in the first opening region, in which the dielectric layer includes a first dielectric structure and a second dielectric structure, and the first dielectric structure has a dielectric material different from a dielectric material of the second dielectric structure; forming a first conductive structure in the first opening region, the conductive structure at least partially wrapped around by the first dielectric structure; removing a portion of the second dielectric structure to form a second opening region; and forming a second conductive structure, the second opening region filled with a portion of the second conductive structure.

Example 15 provides the method according to example 14, in which removing the portion of the second dielectric structure includes removing the portion of the second dielectric structure after the first conductive structure is formed.

Example 16 provides the method according to example 14 or 15, further including forming an insulator layer over the conductive structure and the first conductive structure; and removing a portion of the insulator layer to form a third opening region, the third opening region filled with another portion of the second conductive structure.

Example 17 provides the method according to any one of examples 14-16, in which the second conductive structure is connected to the first conductive structure and to the conductive structure.

Example 18 provides the method according to any one of examples 14-17, further including forming an additional dielectric layer in the opening region, in which the dielectric layer is between the additional dielectric layer and the first conductive structure.

Example 19 provides the method according to any one of examples 14-18, in which forming the dielectric layer in the first opening region includes forming a layer in the first opening region with the dielectric material of the first dielectric structure; removing a portion of the layer to form a third opening region; and providing the dielectric material of the second dielectric structure to the third opening region.

Example 20 provides the method according to any one of examples 14-19, further including coupling the first conductive structure to a power plane.

Example 21 provides an IC package, including the IC device any one of examples 1-20; and a further IC component, coupled to the IC device.

Example 22 provides the IC package according to example 21, where the further IC component includes one of a package substrate, an interposer, or a further IC die.

Example 23 provides the IC package according to example 21 or 22, where the IC device may include, or be a part of, at least one of a memory device, a computing device, a wearable device, a handheld electronic device, and a wireless communications device.

Example 24 provides an electronic device, including a carrier substrate; and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a transistor comprising a source region, a drain region, and an electrode over the source region or the drain region;
a first conductive structure at least partially over the source region or the drain region in a first direction;
a second conductive structure connected to the first conductive structure and the electrode, the second conductive structure comprising a first portion and a second portion; and
a dielectric structure at a first side of the first conductive structure,
wherein:
the first portion of the second conductive structure is over the electrode in a second direction that is perpendicular to the first direction,
the second portion of the second conductive structure is at a second side of the first conductive structure, and
the second side opposes the first side in the first direction.

2. The IC device according to claim 1, wherein:
the dielectric structure abuts a first portion of the first conductive structure,
a second portion of the first conductive structure is wrapped around by an additional dielectric structure, and
the second portion of the first conductive structure is over the first portion of the first conductive structure in the second direction.

3. The IC device according to claim 2, wherein the dielectric structure has a different dielectric material from the additional dielectric structure.

4. The IC device according to claim 1, wherein the electrode is over the source region, the transistor further comprises an additional electrode over the drain region, and the dielectric structure is between the first conductive structure and the additional electrode.

5. The IC device according to claim 1, wherein the first conductive structure is coupled to a power plane.

6. The IC device according to claim 5, further comprising:
a support structure comprising a semiconductor material, the support structure having a first surface and a second surface opposing the first surface in the second direction,
wherein the second conductive structure is closer to the first surface of the support structure than to the second surface of the support structure.

7. The IC device according to claim 6, wherein the power plane is closer to the second surface of the support structure than to the first surface of the support structure.

8. An integrated circuit (IC) device, comprising:
a power plane;
a via coupled to the power plane, the via having a first surface and a second surface opposing the first surface;
an electrode over a semiconductor region of a transistor;
a conductive structure connected to the via and to the electrode; and
a dielectric structure,
wherein the dielectric structure abuts the first surface of the via, and a portion of the conductive structure abuts the second surface of the via.

9. The IC device according to claim 8, further comprising:
an additional electrode over an additional semiconductor region of the transistor, wherein the additional electrode is coupled to a ground plane.

10. The IC device according to claim 8, further comprises:
an additional dielectric structure over the dielectric structure and the portion of the conductive structure, wherein the additional dielectric structure abuts the first surface and the second surface of the via.

11. The IC device according to claim 10, wherein the additional dielectric structure has a different dielectric material from the dielectric structure.

12. The IC device according to claim 8, further comprising:
a layer comprising an electrical insulator; and
a support structure over the layer, the support structure comprising a semiconductor material,
wherein the layer is between the electrode and the support structure.

13. The IC device according to claim 12, wherein the via extends from a first surface of the layer to a second surface of the layer.

14. A method of forming an integrated circuit (IC) device, the method comprising:
forming a first opening region between semiconductor structures, at least part of the opening region surrounded by a conductive structure;
forming a dielectric layer in the first opening region, wherein the dielectric layer comprises a first dielectric structure and a second dielectric structure, and the first dielectric structure has a dielectric material different from a dielectric material of the second dielectric structure;
forming a first conductive structure in the first opening region, the conductive structure at least partially wrapped around by the first dielectric structure;
removing a portion of the second dielectric structure to form a second opening region; and
forming a second conductive structure, the second opening region filled with a portion of the second conductive structure.

15. The method according to claim 14, wherein removing the portion of the second dielectric structure comprises removing the portion of the second dielectric structure after the first conductive structure is formed.

16. The method according to claim 14, further comprising:
forming an insulator layer over the conductive structure and the first conductive structure; and
removing a portion of the insulator layer to form a third opening region, the third opening region filled with another portion of the second conductive structure.

17. The method according to claim 14, wherein the second conductive structure is connected to the first conductive structure and to the conductive structure.

18. The method according to claim 14, further comprising:
forming an additional dielectric layer in the opening region, wherein the dielectric layer is between the additional dielectric layer and the first conductive structure.

19. The method according to claim 14, wherein forming the dielectric layer in the first opening region comprises:
forming a layer in the first opening region with the dielectric material of the first dielectric structure;
removing a portion of the layer to form a third opening region; and
providing the dielectric material of the second dielectric structure to the third opening region.

20. The method according to claim 14, further comprising:
coupling the first conductive structure to a power plane.
